(19) United States
(12) Patent Application Publication
(10) Pub. No.: US 2015/0027875 A1
(43) Pub. Date: Jan. 29, 2015

(54) DEPOSITION APPARATUS AND METHOD FOR MANUFACTURING DISPLAY APPARATUS USING THE DEPOSITION APPARATUS

(71) Applicant: Samsung Display Co., Ltd., Yongin-City (KR)

(72) Inventor: Ou-Hyen Kim, Yongin-City (KR)

(73) Assignee: Samsung Display Co., Ltd., Yongin-City (KR)

(21) Appl. No.: 14/153,660

(22) Filed: Jan. 13, 2014

(30) Foreign Application Priority Data
Jul. 29, 2013 (KR) 10-2013-008982307

(51) Int. Cl. C23C 14/35

(52) U.S. Cl. CPC C23C 14/35
USPC 204/192.12; 204/298.15; 204/298.09

(57) ABSTRACT

A deposition apparatus may include a first substrate mounting member and a second substrate mounting member that may overlap the first substrate mounting member. The deposition apparatus may further include a sputter unit disposed in a space located between the first substrate mounting member and the second substrate mounting member. The sputter unit may have a first opening and a second opening. The first opening may be disposed closer to the first substrate mounting member than the second opening. The second opening may be disposed closer to the second substrate mounting member than the first opening. A first set of material and a second set of material may be simultaneously provided through the first opening and the second opening, respectively.

### RELATED APPLICATIONS

This application claims the benefit of Korean Patent Application No. 10-2013-0089823, filed on Jul. 29, 2013, in the Korean Intellectual Property Office, the disclosure of which is incorporated herein in its entirety by reference.

### BACKGROUND

1. Field

The present invention is related to a deposition apparatus and a method for manufacturing a display apparatus using the deposition apparatus.

2. Description of the Related Art

A display apparatus may include a light-emitting device (e.g., an organic light-emitting device) for emitting light, thereby displaying images. The display apparatus may further include an encapsulating element for protecting the light-emitting device from environmental substances, such as moisture. The encapsulation element may be formed through one or more deposition processes performed using a deposition apparatus.

### SUMMARY

One or more embodiments of the present invention may be related to a deposition apparatus that may be associated with substantially satisfactory deposition efficiency. One or more embodiments of the present invention may be related to a method for manufacturing a display apparatus using the deposition apparatus.

An embodiment of the present invention may be related to a deposition apparatus that may include a first substrate mounting member and a second substrate mounting member that overlap each other and are configured to support a first substrate and a second substrate, respectively. The deposition apparatus may further include a sputter unit disposed in a space located between the first substrate mounting member and the second substrate mounting member. The sputter unit may have a first opening and a second opening. The first opening may be disposed closer to the first substrate mounting member than the second opening. The second opening may be disposed closer to the second substrate mounting member than the first opening. A first set of material and a second set of material may be simultaneously provided through the first opening and the second opening, respectively, toward the first substrate and the second substrate, respectively.

The deposition apparatus may include the following elements: a chamber that contains the sputter unit; and a driving unit configured to move at least one of the first substrate mounting member and the second substrate mounting member with respect to at least one of the chamber and the sputter unit.

The first substrate mounting member may have an opening that is located between two portions of the first substrate mounting member. A width of the opening parallel to a first coordinate axis (e.g., perpendicular to a ground surface that supports the sputter unit) is equal to or greater than a length of the sputter unit in a direction parallel to the first coordinate axis (and/or parallel to a direction of the width of the opening).

The two portions of the first substrate mounting member may not overlap the sputter unit in a direction perpendicular to the first coordinate axis (and/or perpendicular to the direction of the width of the opening).

The first substrate mounting member and the second substrate mounting member may be configured to simultaneously move in a same direction with respect to the sputter unit.

The first opening may be located at a first side of the sputter unit. The second opening may be located at a second side of the sputter unit that is parallel to the first side of the sputter unit. The first opening may overlap and/or may be aligned with the second opening in a direction perpendicular to the first side of the sputter unit.

The deposition apparatus may include a first target support member and second target support member that are disposed between the first side of the sputter unit and the second side of the sputter unit. The first target support member may overlap and/or may be aligned with the second target support member in a direction parallel to the first side of the sputter unit.

The deposition apparatus may include a control unit configured to control a height of the sputter unit in a direction parallel to an extension direction of the first substrate mounting member and/or parallel to a surface of the first substrate that faces the sputter unit.

The deposition apparatus may include the following elements: a first press plate configured to secure the first substrate on the first substrate mounting member; and a second press plate disposed parallel to the first press plate and configured to secure the second substrate on the second substrate mounting member.

The deposition apparatus may include a target support member that is disposed inside the sputter unit and has a support surface configured to contact a target, which may include the first set of material and the second set of material. The first press plate may have a contact surface disposed perpendicular to the support surface and configured to contact the first substrate. The first press plate may include a flow passage disposed perpendicular to the support surface and configured to transmit a refrigerant for cooling the first substrate.

The deposition apparatus may include a pipe that is connected to a flow passage of the first press plate and connected to a connection unit of the first substrate mounting member. The flow passage of the first press plate may receive a refrigerant provided through the connection unit of the first substrate mounting member and may transmit the refrigerant to cool the first substrate.

The deposition apparatus may include a tube that may be connected to the connection unit of the first substrate mounting member, may transmit the refrigerant to the connection unit of the first substrate mounting member, and may deform when the first substrate mounting member moves with respect to the sputter unit.

An embodiment of the present invention may be related to a method for manufacturing a display apparatus. The method may include the following steps: disposing a sputter unit between a first display unit and a second display unit, the sputter unit having a first opening and a second opening, the first display unit being disposed on a first substrate, the second display unit being disposed on a second substrate; and simultaneously providing a first set of material through the first opening onto the first display unit and providing a second set of material through the second opening onto the second display unit.

At least one of the first set of material and the second set of material may include a low temperature viscosity transition (LVT) inorganic material.

The method may include the following step: simultaneously moving the first display unit and the second display unit in a same direction with respect to the sputter unit.

The method may include the following step: mounting the first substrate on a first substrate mounting member. The first substrate mounting member may have an opening located between two portions of the first substrate mounting member. A width of the opening parallel to a first coordinate axis is equal to or greater than a length of the sputter unit parallel to the first coordinate axis.

The two portions of the first substrate mounting member may not overlap the sputter unit in a direction perpendicular to the first coordinate axis.

The method may include the following steps: mounting the first substrate on a first substrate mounting member; using a press plate to secure the first substrate on the first substrate mounting member; and providing a refrigerant through a flow passage of the press plate to cool the first substrate.

The method may include the following steps: supporting the sputter unit on a ground surface; and disposing each of the first substrate and the second substrate perpendicular to the ground surface.

An embodiment of the present invention may be related to a deposition apparatus that may include the following elements: a chamber; a pair of substrate mounting members disposed inside the chamber and overlapping each other, wherein substrates may be mounted respectively on the substrate mounting members; and a sputter unit disposed between the substrate mounting members, wherein the sputter unit may include the following elements: a pair of target support members for supporting a pair of targets such that the targets may face each other; and a first opening and a second opening that are oriented perpendicular to the targets, and wherein the first opening and the second opening may face the substrate mounting members respectively.

The pair of substrate mounting members may be disposed perpendicular to the ground.

An opening may be formed at each of the substrate mounting members, and a vertical width of the opening may be equal to or greater than a length of the sputter unit.

An edge of each of the substrate mounting members may not overlap the sputter unit.

The pair of substrate mounting members may move in one direction in the chamber.

The sputter unit may have a rectangular hexahedron shape, and the first opening and the second opening may be formed on a pair of parallel side surfaces of the sputter unit.

The pair of targets may be disposed on another pair of side surfaces of the sputter unit.

The pair of targets may be formed of a low temperature viscosity transition (LVT) inorganic material.

The sputter unit may include the following elements: a control unit for controlling a height of the sputter unit; and a support portion for supporting other elements of the sputter unit.

The deposition apparatus may include a press plate for fixing a position of a substrate. The press plate may include the following elements: a flow passage through which a refrigerant may flow to cool the substrate; an injection portion through which the refrigerant may be injected into the flow passage; and a discharge portion through which the refrigerant may be discharged from the flow passage.

An embodiments of the present invention may be related to a deposition apparatus that may include the following elements: a chamber; a pair of substrate mounting members disposed in the chamber and disposed perpendicular to the ground; and a sputter unit disposed between the substrate mounting members. The sputter unit may have a rectangular hexahedron shape. The sputter unit may have a first opening and a second opening that are formed on a pair of parallel side surfaces of the sputter unit. The first opening and the second opening may face the substrate mounting members respectively.

The sputter unit may include a pair of target support members for supporting a pair of targets such that the targets may face each other and may be disposed perpendicular to the first opening and the second opening.

Substrates may be mounted respectively on the substrate mounting members. Two sets of material provided from the targets may be simultaneously provided through the first opening and the second opening and may be simultaneously deposited on the substrates,.

The deposition apparatus may include a press plate for fixing a position of the substrate. The press plate may include the following elements: a flow passage through which a refrigerant may flow for cooling the substrate; an injection portion through which the refrigerant may be injected into the flow passage; and a discharge portion through which the refrigerant may be discharged from the flow passage.

The injection portion may be connected through a pipe to a connection portion formed at one side of a substrate mounting member. The connection portion may be connected to a tube connected to a refrigerant tank. The tube may be flexible.

An opening may be formed at each of the substrate mounting members. A vertical width of the opening may be equal to or greater than a length of the sputter unit.

An edge of each of the substrate mounting members may not overlap with the sputter unit.

An embodiment of the present invention may be related to a method for manufacturing a display apparatus, e.g., an organic light-emitting display apparatus. The method may include the following steps: forming a display unit on each of two substrates; disposing the substrates in a chamber such that the substrates may be be perpendicular to the ground and may face each other; and forming an encapsulation layer to seal the display unit formed on each of the substrates. The encapsulation layer may be formed by sputtering using a sputter unit that may sputter a pair of targets that include a low temperature viscosity transition (LVT) inorganic material and face each other. The sputter unit may include a first opening and a second opening that correspond respectively to the substrates. During sputtering, two subsets of the LVT inorganic material may pass through the first opening and the second opening, respectively, and may be simultaneously deposited on the substrates, respectively, to cover the display units.

A position of each of the substrates may be fixed by a press plate. The press plate may have a flow passage through which a refrigerant flows, and the substrates may be cooled by the refrigerant during the sputtering.

Each of the substrates may be mounted on a substrate mounting member. An edge of the substrate mounting member may not overlap the sputter unit. The substrate mounting members may move in one direction in the chamber during the sputtering.

### BRIEF DESCRIPTION OF THE DRAWINGS

FIG. 1 is a schematic cross-sectional view illustrating a display apparatus, e.g., an organic light-emitting display apparatus, according to an embodiment of the present invention.

FIG. 2 is a schematic cross-section view illustrating a portion P indicated in FIG.

FIG. 3 is a schematic view illustrating a deposition apparatus for forming an encapsulation layer of a display apparatus, e.g., an encapsulation layer of an organic light-emitting display apparatus illustrated in FIG. 1, according to an embodiment of the present invention.

FIG. 4 is a schematic cross-sectional view illustrating a sputter unit of the deposition apparatus illustrated in FIG. 3 according to an embodiment of the present invention.

FIG. 5 is a schematic cross-sectional view illustrating the deposition apparatus illustrated in FIG. 3 according to an embodiment of the present invention.

FIG. 6 is a schematic plan view illustrating a press plate of the deposition apparatus illustrated in FIG. 3 according to an embodiment of the present invention.

### DETAILED DESCRIPTION

Examples of embodiments of the present invention are described with reference to the accompanying drawings, wherein like reference numerals may refer to identical and/or analogous elements. Embodiments of the invention may have different forms and should not be construed as being limited to the description set forth herein.

As used herein, the term “and/or” may include any and all combinations of one or more of the associated items. Expressions such as “at least one of,” when preceding a list of elements, modify the entire list of elements and do not modify the individual elements of the list.

The present invention may include various embodiments and modifications and is not limited to the described examples of embodiments. In the description, detailed descriptions of well-known functions or configurations may be omitted for conciseness and/or clarity.

Although terms such as “first”, “second”, etc. may be used herein to describe various elements, these elements should not be limited by these terms. These terms may be used to distinguish one element from another element. Thus, a first element may be termed a second element without departing from the teachings of the present invention. The description of an element as a “first” element may not require or imply the presence of a second element or other elements. The terms “first”, “second”, etc. may also be used herein to differentiate different categories of elements. For conciseness, the terms “first”, “second”, etc. may represent “first-type (or first-category)”, “second-type (or second-category)”, etc., respectively.

In the description, the term “connect” may mean “electrically connect”; the term “insulate” may mean “electrically insulate”; the term “conductive” may mean “electrically conductive”.

The singular forms “a”, “an”, and “the” may include the plural forms as well, unless the context clearly indicates otherwise. Terms such as “comprise”, “include”, and “have”, when used herein, specify the presence of stated features, integers, steps, operations, elements, components, or combinations thereof, but do not preclude the presence or addition of one or more other features, integers, steps, operations, elements, components, or combinations thereof.

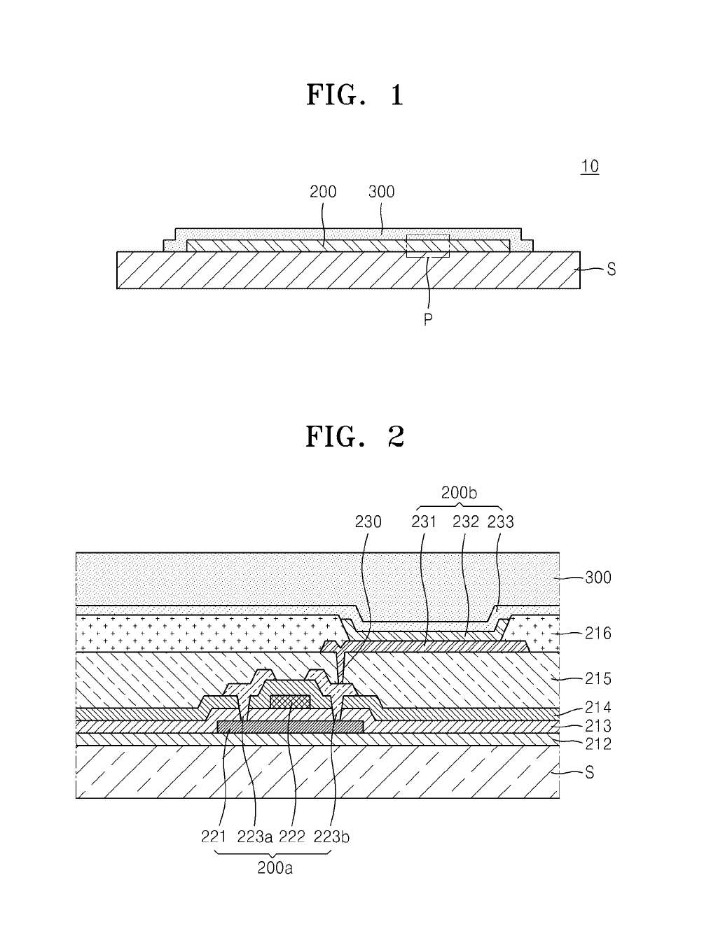

FIG. 1 is a schematic cross-sectional view illustrating a display apparatus 10 (e.g., an organic light-emitting display apparatus 10) according to an embodiment of the present invention. FIG. 2 is a schematic cross-section view illustrating a portion P indicated in FIG. 1.

Referring to FIG. 1, the organic light-emitting display apparatus 10 may include a substrate S, a display unit 200 formed on the substrate S, and an encapsulation layer 300 that may substantially encapsulate the display unit 200.

The substrate S may be or may include a transparent glass substrate formed mainly of SiO₂. The substrate S may be or may include a plastic substrate formed of a transparent plastic material. The transparent plastic material may be an insulating organic material and may include at least one of polyether sulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAO), and cellulose acetate propionate (CAP).

The organic light-emitting display apparatus 10 may be a bottom emission type display apparatus that displays an image through the substrate S, and the substrate S may be transparent. The organic light-emitting display apparatus 10 may be a top emission type display apparatus that displays an image through a surface opposite the substrate S, and the substrate S may not need to be transparent. In an embodiment, the substrate S may be formed of a metal. In an embodiment, the substrate S may include at least one of carbon (C), iron (Fe), chromium (Cr), manganese (Mn), nickel (Ni), titanium (Ti), molybdenum (Mo), and stainless steel (SUS).

As illustrated in FIG. 2, the display unit 200 may include an organic thin film transistor (TFT) 200a and a pixel portion 200b. The pixel portion 200b may be an organic light-emitting device (OLED).

A buffer layer 212 may be formed on the substrate S. The buffer layer 212 may prevent impurity elements from contaminating the TFT 200a and/or may provide a substantially flat surface on the substrate S. The buffer layer 212 may be formed of one or more of various materials that may perform the protection function and/or the flattening function. In an embodiment, the buffer film 212 may be formed of one or more inorganic materials, such as one or more of silicon oxide, silicon nitride, silicon oxynitride, aluminum oxide, aluminum nitride, titanium oxide, titanium nitride, etc. In an embodiment, the buffer film 212 may be formed of one or more organic materials, such as one or more of polyimide, polyester acryl, etc.

The buffer layer 212 may be formed using one or more of various deposition methods, such as one or more of plasma-enhanced chemical vapor deposition (PECVD), atmospheric pressure CVD (APCVD), and low pressure CVD (LPCVD).

The TFT 220a may include an active layer 221, a gate electrode 222, a source electrode 223a, and a drain electrode 223b.

The active layer 221 may be formed on the buffer layer 212. The active layer 221 may be formed of an inorganic semiconductor, such as silicon, or an organic semiconductor. The active layer 221 includes a source region, a drain region, and a channel region disposed between the source region and the drain region. In an embodiment, the active layer 221 is formed of amorphous silicon, and the active layer 221 may be formed by forming an amorphous silicon layer on a surface of the substrate S, crystallizing the amorphous silicon layer to form a polycrystalline silicon layer, patterning the polycrystalline silicon layer, and doping the source region and the drain region.

A gate insulating film 213 is formed on the active layer 221. The gate insulating film 213 may be formed of an inorganic material, such as SiNx or SiO₂, to insulate the active layer 221 from the gate electrode 222.

The gate electrode 222 is formed in a predetermined region on the gate insulating film 213. The gate electrode 222 is connected to a gate line (not illustrated) that is used to apply an on/off signal to the TFT 220a.

The gate electrode 222 may contain at least one of gold (Au), silver (Ag), copper (Cu), Ni, platinum (Pt), palladium (Pd), aluminum (Al), and Mo. The gate electrode 222 may include an alloy, such as an Al-Nd (neodymium) alloy or an Mo-W (tungsten) alloy. The gate electrode 222 may be formed one or more of various materials according to particular embodiments.

An interlayer insulating film 214 is formed on the gate electrode 222. The interlayer insulating film 214 may be formed of an inorganic material, such as SiNx or SiO₂, to insulate the gate electrode 222 from each of the source electrode 223a and the drain electrode 223b.

The source electrode 223a and the drain electrode 223b are formed on the interlayer insulating film 214. Holes may be formed through the interlayer insulating film 214 and the gate insulating film 213 to expose the source region and the drain region of the active layer 221, and the source electrode 223a and the drain electrode 223b may respectively contact the exposed source region and the exposed drain region.

FIG. 2 illustrates a top gate type TFT structure, in which the active layer 221 is disposed between the gate electrode 222 and the substrate S. In an embodiment, the gate electrode 222 may be disposed between the active layer 221 and the substrate S.

The TFT 200a is electrically connected to the pixel portion 200b to drive (i.e., control) the pixel portion 200b. The TFT 200a is covered and/or protected by a planarization film 215.

The planarization film 215 may be or may include an inorganic insulating film and/or an organic insulating film. The inorganic insulating film may include at least one of SiO₂, SiNx, SiON, Al₂O₃, TiO₂, Ta₂O₅, HfO₂, ZrO₂, barium strontium titanate (BST), and lead zirconate titanate (PZT). The organic insulating film may include at least one general-purpose polymer, such as at least one of polymethylmethacrylate (PMMA), polystyrene (PS), a polymer derivative having a phenol-based group, an acryl-based polymer, an imide-based polymer, an arylether-based polymer, an amide-based polymer, a fluorine-based polymer, a p-xylene-based polymer, and a vinylalcohol-based polymer. The planarization film 215 may include an inorganic insulating film and an organic insulating film that overlap each other.

The pixel portion 200b is formed on the planarization film 215. The pixel portion 200b may include a pixel electrode 231, an intermediate layer 232, and an opposite electrode 233.

In an embodiment, the organic light-emitting display apparatus 10 may be a top-emission-type display apparatus. The pixel electrode 231 is formed on the planarization film 215 and is electrically connected to one of the source electrode 223a and the drain electrode 223b through a contact hole 230 formed in the planarization film 215.

The pixel electrode 231 may be a reflection electrode. The pixel electrode 231 may include a reflection film formed of at least one of Ag, magnesium (Mg), Al, Pt, Pd, Au, Ni, neodymium (Nd), iridium (Ir), Cr, and a compound or alloy of some of these materials. The pixel electrode may include a transparent or semitransparent electrode layer formed on the reflection film. The transparent or semitransparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO).

The opposite electrode 233 may overlap the pixel electrode 231 and may be a transparent or semitransparent electrode. The opposite electrode 233 may be formed of a metal thin film having a small work function. The opposite electrode 233 may include at least one of lithium (Li), calcium (Ca), LiF/Ca, LiF/AI, Al, Ag, MG, and a compound or alloy of some of these materials. A bus electrode or an auxiliary electrode formed of a transparent electrode material, such as ITO, IZO, ZnO, or In₂O₃, may be further formed on the metal thin film.

The opposite electrode 233 may transmit light that is emitted from an organic emission layer included in the intermediate layer 232. The light emitted from the organic emission layer may be emitted to the opposite electrode 233 directly and/or may be reflected by the pixel electrode 231, which may be a reflection electrode.

In an embodiment, the organic light-emitting display apparatus 10 may be a bottom-emission-type display apparatus, in which light emitted from the organic emission layer may be transmitted toward the substrate S, the pixel electrode 231 may be a transparent or semitransparent electrode, and the opposite electrode 233 may be a reflection electrode. In an embodiment, the organic light-emitting display apparatus 10 may be a dual emission type display apparatus, in which light is emitted by the organic emission layer may be transmitted toward both the opposite electrode 233 and the substrate S.

A pixel definition film 216 formed of an insulating material may be formed on the pixel electrode 231. The pixel definition film 216 may be formed of at least one organic insulating material, such at least one of polyimide, polyamide, acryl resin, benzocyclobutene, and phenol resin. The pixel definition film 216 may be formed by spin coating. The pixel definition film 216 exposes a predetermined region of the pixel electrode 231, and the intermediate layer 232, which includes the organic emission layer, is disposed in the exposed region.

The organic emission layer included in the intermediate layer 232 may be formed of a low-molecular organic material or a polymer organic material. The intermediate layer 232 may further include one or more functional layers, such as one or more of a hole transport layer (HTL), a hole injection layer (HIL), an electron transport layer (ETL), and an electron injection layer (EIL), in addition to the organic emission layer.

Referring to FIG. 1, the encapsulation layer 300 may substantially completely cover the display unit 200, thereby substantially preventing moisture or oxygen from penetrating into and/or contaminating the display unit 200. In an embodiment, the encapsulation layer 300 may be larger than the display unit 200 such that all edges of the encapsulation layer 300 may contact the substrate S, thereby substantially securely encapsulating the display unit 200.

The encapsulation layer 300 may be formed of a low temperature viscosity transition (LVT) inorganic material. The LVT inorganic material may have a minimum viscosity transition temperature such that the LVT inorganic material may be fluid at temperatures above the minimum viscosity transition temperature. The minimum viscosity transition temperature of the LVT inorganic material may be lower than a metamorphic temperature, at which chemical and/or physical metamorphism of one or more materials included in the display unit 200 may occur.

The LVT inorganic material may include tin oxide (for example, SnO or SnO₂). In an embodiment, the LVT inorganic material includes SnO, and the content of SnO may be in a range of about 20 wt % to about 100 wt %.

The LVT inorganic material may include one or more of phosphorus oxide (for example, P₂O₅), boron phosphate (BPO₄), tin fluoride (for example, SnF₂), niobium oxide (for example, NbO), tungsten oxide (for example, WO₃), etc.

The LVT inorganic material may include one or more of the following: 1) SnO; 2) SnO and P₂O₅; 3) SnO and BPO₄; 4) SnO, SnF₂, and P₂O₅; 5) SnO, SnF₂, P₂O₅, and NbO; or 6) SnO, SnF₂, P₂O₅, and WO₃, etc.

The LVT inorganic material may have one or more of the following compositions: 1) SnO (about 100 wt %); 2) SnO (about 80 wt %) and P₂O₅ (about 20 wt %); 3) SnO (about 90 wt %) and BPO₄ (about 10 wt %); 4) SnO (about 20 wt % to about 50 wt %), SnF₂ (about 30 wt % to about 60 wt %), and P₂O₅ (about 10 wt % to about 30 wt %); 5) SnO (about 20 wt % to about 50 wt %), SnF₂ (about 30 wt % to about 60 wt %), P₂O₅ (about 10 wt % to about 30 wt %), and NbO (about 1 wt % to about 5 wt %); or 6) SnO (about 20 wt % to about 50 wt %), SnF₂ (about 30 wt % to about 60 wt %), P₂O₅ (about 10 wt % to about 30 wt %), and WO₃ (about 1 wt % to about 5 wt %), etc.

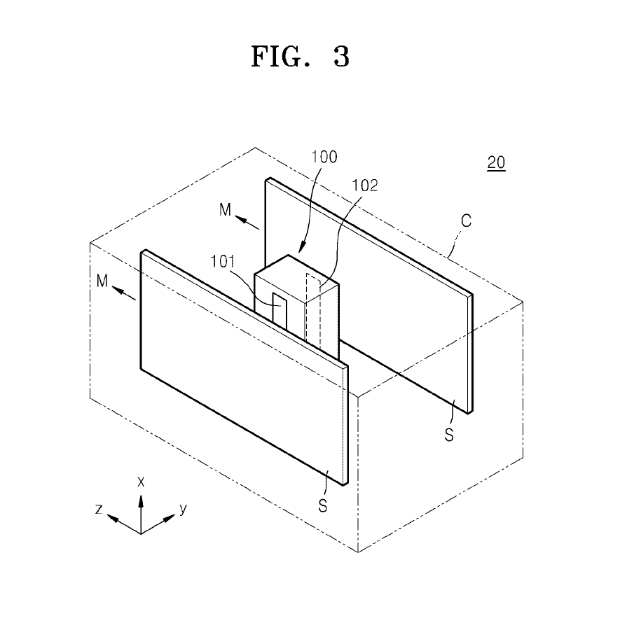

The encapsulation layer 300 may be formed using a deposition apparatus 20 illustrated in FIG. 3. The deposition apparatus 20 may simultaneously form two substrates S, such that a deposition process yield may be maximized. A distance between each substrate S and a sputter unit 100 of the deposition apparatus 20 may be minimized, such that deposition process efficiency may be maximized. The deposition apparatus 20 may cool substrates S during a deposition process, thermal metamorphism of materials of the organic light-emitting display device 10 may be substantially prevented.

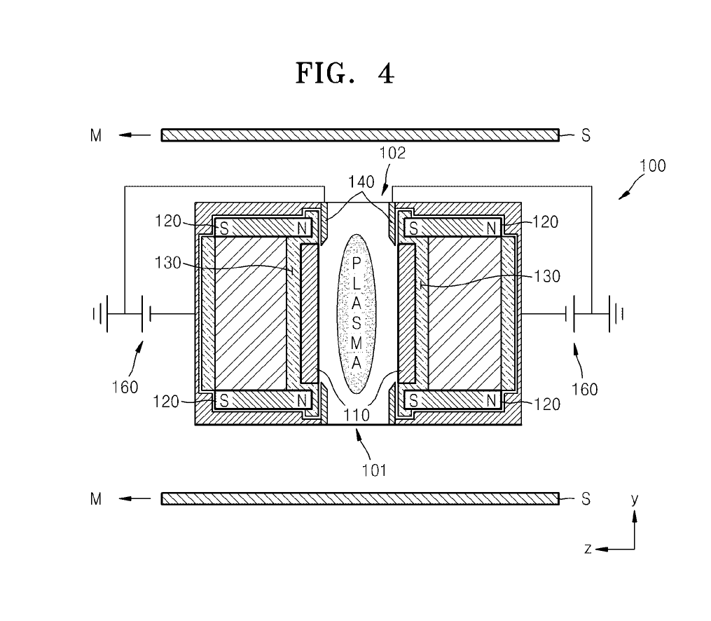

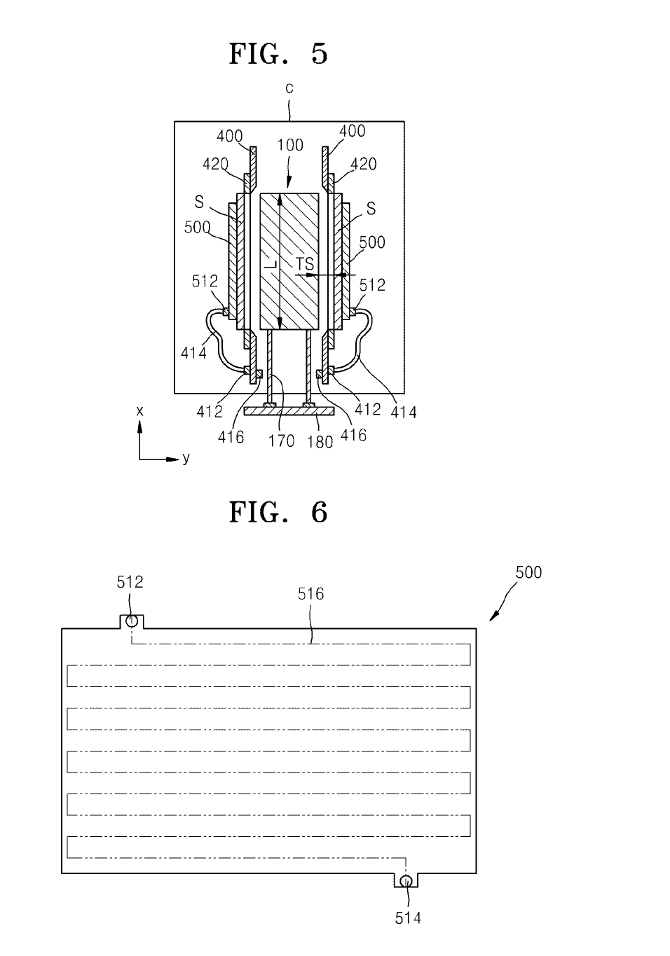

FIG. 3 is a schematic view illustrating a deposition apparatus 20 for forming an encapsulation layer of a display device, e.g., the encapsulation layer 300 of the organic light-emitting display apparatus 10 illustrated in FIG. 1, according to an embodiment of the present invention. FIG. 4 is a schematic cross-sectional view illustrating a sputter unit 100 of the deposition apparatus 20 according to an embodiment of the present invention. FIG. 5 is a schematic cross-sectional view illustrating the deposition apparatus 20 according to an embodiment of the present invention. FIG. 6 is a schematic plan view illustrating a press plate 500 of the deposition apparatus 20 according to an embodiment of the present invention.

Referring to FIGS. 3 to 6, the deposition apparatus 20 may include the following elements: a chamber C; a pair of substrate mounting members 400 that may be disposed inside the chamber C and spaced apart from each other; and a sputter unit 100 disposed between the two substrate mounting members 400. The deposition apparatus 20 may further include a pair of press plates 500 for securing substrates S.

The chamber C may accommodate the sputter unit 100 and the substrate mounting members 400. The chamber C may be connected to a vacuum pump (not illustrated) to control a pressure inside the chamber C. The chamber C may have one or more gateways (not illustrated) through which the substrate mounting members 400 may enter and exist.

As illustrated in FIGS. 3 to 5, the pair of substrate mounting members 400 may be disposed parallel to each other inside the chamber C, and two substrates S may be mounted on the two substrate mounting members 400, respectively. The substrates S may be parallel to the Z axis. The substrate mounting members 400 may move the substrates S in the movement direction M parallel to the Z axis during the deposition process, such that material may be deposited on different portions of each of the substrates S.

The pair of substrate mounting members 400 may be oriented parallel to the X axis and disposed perpendicular to the ground and may transfer the substrates S into the chamber C. Each of the substrate mounting members 400 may include or be connected to a driving unit (not illustrated) for performing movement. The substrate mounting members 400 may be symmetrical to each other with respect to the sputter unit 100. A distance between the sputter unit 100 and a first one of the substrate mounting members 400 may be equal to a distance between the sputter unit 100 and a second one of the substrate mounting members 400, wherein each of the distances may be parallel to the Y axis. The driving units (not illustrated) respectively included in or connected to the substrate mounting members 400 may have the same structure. Therefore, the entire structure of the deposition apparatus 20 may be substantially simple.

An edge of a substrate mounting member 400 may contact a mask 420 and/or a substrate S. An opening for enabling deposition may be formed at a center of the substrate mounting member 400 and/or the mask 420. A vertical width of the opening may be equal to or greater than a length L of the sputter unit 100. The vertical width of the opening may mean the width of the opening that is measured in the vertical direction perpendicular to the ground when the substrate mounting member 400 is disposed to be perpendicular to the ground, and the length L of the sputter unit 100 may mean the width of the sputter unit 100 in the vertical direction perpendicular to the ground.

Accordingly, the edge(s) of the substrate mounting portion 400 may not overlap the sputter unit 100, and thus a distance TS between the substrate S and the sputter unit 100 may be minimized. Therefore, a deposition rate of a deposition material deposited on the substrate S may be maximized.

The sputter unit 100 is disposed between the substrate mounting members 400 and may simultaneously form thin films on the two substrates S mounted on the two substrate mounting members 400 by sputtering.

The sputter unit 100 may include the following elements: two target support members 130 (e.g., magnetic chucks, electrostatic chucks, or yoke plates) for supporting two targets 110 such that the targets 110 may face each other; and a first opening 101 and a second opening 102 through which a deposition material separated (and provided) from the targets 110 may diffuse to the substrates S.

The pair of targets 110 may function as a cathode when power is applied to the sputter unit 100. The targets 110 may include an LVT inorganic material for forming the encapsulation layer 300.

The LVT inorganic material may include tin oxide (for example, SnO or SnO₂) and may further include one or more of phosphorus oxide (for example, P₂O₅), boron phosphate (BPO₄), tin fluoride (for example, SnF₂), niobium oxide (for example, NbO), and tungsten oxide (for example, WO₃). For example, each of the targets 110 may include SnO (about 42.5 wt %), SnF₂ (about 40 wt %), P₂O₅ (about 15 wt %), and WO₃ (about 2.5 wt %).

The LVT inorganic material is separated from the target 110 by sputtering. The first opening 101 and the second opening 102 may respectively correspond to the two substrate mounting members 400. The separated LVT inorganic material may pass through the first opening 101 and the second opening 102 and move toward the substrates S that are mounted on the substrate mounting members 400 disposed at two sides of the sputter unit 100. Therefore, encapsulation layers 300 may be simultaneously formed on the two substrates S.

In an embodiment, the sputter unit 100 may have a rectangular hexahedron shape, and the first opening 101 and the second opening 102 may be formed on two opposite side surfaces that are parallel to the substrate mounting members 400. The targets 110 may be disposed perpendicular to the two side surfaces of the sputter unit 100 where the first opening 101 and the second opening 102 are located.

A length of each of the first opening 101 and the second opening 102 may correspond to the height of the substrate S or a length of the encapsulation layers 300 to be formed. A width of each of the first opening 101 and the second opening 102 may be related to a distance between the targets 110. The distance between the targets 110 may be minimized, and/or a surface area of each target 110 may be maximized, for maximizing the efficiency of the deposition process performed using the deposition apparatus 20.

Referring to FIG. 4 and FIG. 5, the sputter unit 100 may further include the following elements: magnetic field generating units 120 for generating a magnetic field; target support members 130 for supporting the targets 110; and shield members 140 for shielding the magnetic field generating units 120 and/or the target support members 130 and for functioning as an anode. The sputter unit 100 may further include the following elements: a control unit 170 that may control the height of the sputter unit 100; and a support portion 180 that may support other elements of the sputter unit 100.

The magnetic field generating units 120 may be disposed at edges of the targets 110. Each magnetic field generating unit 120 may be formed of a ferromagnet, such as a ferrite-based magnet, a neodium-based (for example, neodium, iron, or boron) magnet, or a samarium cobalt-based magnet and may be disposed along an outer periphery of a target 110.

Two opposite magnetic field generating units 120 respectively corresponding to the two targets 110 may have opposite polarity arrangements, in order to restrict a plasma generation region within a space between the targets 110.

The target support member 130 is configured such that a magnetic field formed by the magnetic field generating units 120 may be uniformly distributed in the space between the targets 110. A target support member 130 may be formed of a material that may have magnetism induced by a magnetic field generating unit 120. For example, the target support member 130 may be formed of at least one ferromagnetic material, such as at least one of iron, cobalt, nickel, and an alloy of some of the materials.

Two shield members 140 may be disposed at two edge of each target 110. Each shield member 140 may function as an anode by being grounded. Each shield member 140 may be disposed slightly spaced apart from the associated target 110. Each shield member 140 may be configured to avoid being substantially sputtered. Two shield members 140 may be disposed between two opposite magnetic field generating units 120 that respectively correspond to the two target support members 130. Two shield members 140 may be disposed between portions of the two target support members 130.

A screw thread may be formed at the control unit 170 to control the height of the sputter unit 100. The support portion 180 may be formed at the lower end of the control unit 170 and may fix the sputter unit 100 at a predetermined location.

The sputter unit 100 may generate plasma by applying power to the pair of targets 110. In an embodiment, inert gas (such as argon gas) is injected between the targets 110, and power is applied to the pair of targets 110; as a result, electric discharge occurs in the space between the pair of targets 10, and electrons generated by the electric discharge collide with the argon gas, thereby generating argon ions to separate particles from the targets 110 and thus generating plasma.

Power may be supplied to the pair of targets 110 by a power supply unit 160, which may be a direct current (DC) power supply. In an embodiment, the power supply unit 160 may be a DC pulse power supply or a radio frequency (RF) power supply that uses a DC offset voltage.

The plasma is formed between the targets 110 by the magnetic field generated by the magnetic field generating unit 120. Charged high-energy particles in the plasma, such as electrons, negative ions, and positive ions, may reciprocate and may be substantially restricted between the targets 110 along magnetic lines. Thin films may be formed on the substrates S by neutron particles that have relatively low energy. High-energy particles sputtered from either target 110 may accelerate toward the opposite target 110, without affecting the substrates S, which are disposed perpendicular to the sputtered surfaces of the targets 110. Therefore, damage to the substrate S potentially caused by collision of high-energy particles may be substantially prevented or minimized.

The neutron particles, which have relatively low energy, may pass through the first opening 101 and the second opening 102 and move toward the two substrates mounted on the two substrate mounting members 400 disposed at two sides of the sputter unit 100. Accordingly, the deposition apparatus 20 may simultaneously form thin films on the two substrates S. Advantageously, the deposition process yield may be maximized.

The temperature of the targets 110 may increase as a result of the repeated collision of particles. Thus, the sputter unit 100 may further include a cooling device (not illustrated) for decreasing and/or maintaining the temperature of the targets 110 during a sputtering process. The cooling device may include a flow passage through which a refrigerant may flow.

During the deposition process, each press plate 500 may secure a substrate S in a position perpendicular to the ground. In an embodiment, in the deposition process, the substrate S is located between a substrate mounting member 400 and the press plate 500, and the press plate 500 may contact one surface of the substrate S and may press the substrate S toward the substrate mounting portion 400. Accordingly, the substrate S may be secured in place, such that shift or shake of the substrate S may be substantially prevented or minimized, and thus a thin film may be formed at an accurate position of the substrate S.

The press plate 500 may include a flow passage through which a refrigerant may flow. Therefore, when the press plate 500 closely contacts one surface of the substrate S to fix the substrate S, the refrigerant flowing through the flow passage may cool the substrate S through heat transfer.

FIG. 6 is a schematic plan view of the press plate 500. Referring to FIG. 6, the press plate 500 may include the following elements: a flow passage 516 through which a refrigerant may flow; an injection unit 512 through which the refrigerant may be injected into the flow passage 516; and a discharge unit 514 through which the refrigerant may be discharged from the flow passage 516.

Various types of refrigerant may be used, and the refrigerant may be supplied from an external refrigerant tank (not illustrated). In an embodiment, as illustrated in FIG. 5, the injection unit 512 may be connected through a pipe 414 to a connection unit 412 formed at one side of the substrate mounting member 400, and the connection unit 412 may be connected to a tube 416 connected to the refrigerant tank (not illustrated). The refrigerant discharged from the discharge unit 514 may be discharged (e.g., to a collection container) through the substrate mounting unit 400.

The tube 416 may be flexible. Thus, when the substrate mounting member 400 moves, the tube 416 may deform (e.g., change from a first shape to a second shape) accordingly. Therefore, in the deposition process, the substrate S may be effectively cooled even when the substrate S moves, and thus the thermal metamorphism of materials of the organic light-emitting device may be prevented.

In an embodiment, a method for manufacturing the organic light-emitting display apparatus 10 illustrated in FIG. 1 may include the following steps: forming a display unit 200 on each of two substrates S; and forming an encapsulation layer 300 for sealing each display unit 200. The display unit 200 may be manufactured using one or more known methods.

The forming of the encapsulation layer 300 may include the following steps: disposing the two substrates S, on which the display units 200 have been formed, in a chamber C; and simultaneously forming two encapsulation layers 300 on the two substrates S, respectively, by sputtering using a sputter unit 100.

The two substrates S may be respectively mounted on two substrate mounting members 400 and may be respectively secured by two press plates 500. In an embodiment, a mask 420 may be provided on each substrate mounting member 400.

The two substrate mounting members 400 are disposed perpendicular to the ground and face each other with the sputter unit 100 being disposed between the two substrate mounting members 400. The two substrates S respectively mounted on the two substrate mounting members 400 are also disposed perpendicular to the ground with the sputter unit 100 being disposed between the two substrates S.

The height of the sputter unit 100 (in a direction parallel to the X axis and perpendicular to the ground) is controlled by a control unit. A first opening 101 and a second opening 102 of the sputter unit 100 may face the two substrates S, respectively.

The encapsulation layers 300 may be formed when the two substrates S move in the movement direction M. In an embodiment, particles of an LVT inorganic material may be separated from two targets 110 by sputtering, and a first set and a second set of the separated particles of the LVT inorganic material may pass through the first opening 101 and the second opening 102, respectively, and may be simultaneously deposited on the two substrates S, respectively. Advantageously, the manufacturing process yield associated with the organic light-emitting display apparatus 10 may be maximized.

Edges of the two substrate mounting members 400 may not contact the sputter unit 100. That is, the vertical width(s) of two openings respectively formed (in a direction parallel to the X axis and perpendicular to the ground) at the two substrate mounting members 400 may be equal to or greater than the length L of the sputter unit 100. Therefore, the distance TS (in a direction parallel to the Y axis) between each substrate S and the sputter unit 100 may be minimized. Advantageously, the deposition efficiency may be improved. In an embodiment, in the deposition process, a refrigerant may flow through the press plate 500s, which may contact the substrates S, to cool the substrates S, such that thermal metamorphism of materials of the display unit 200 may be substantially prevented or minimized. Advantageously, satisfactory quality of the organic light-emitting display apparatus 10 may be provided.

As can be appreciated from the description, according to embodiments of the present invention, the deposition apparatus may simultaneously form thin films on two substrates. Advantageously, the deposition process yield may be maximized.

According to embodiments of the invention, the distance between each substrate and the sputter unit may be minimized in the deposition process. Advantageously, the deposition efficiency may be maximized.

According to embodiments of the invention, substrates may be cooled during the deposition process, such that thermal metamorphism of materials of the manufactured display apparatus may be substantially prevented or minimized. Advantageously, satisfactory quality of the display apparatus may be provided.

The embodiments described above are for illustration and not for limitation. Those of ordinary skill in the art would understand that various changes may be made to the embodiments without departing from the spirit and scope of the present invention as defined by the following claims.

What is claimed is:

1. A deposition apparatus comprising:
a first substrate mounting member;
a second substrate mounting member overlapping the first substrate mounting member; and
a sputter unit disposed in a space located between the first substrate mounting member and the second substrate mounting member, the sputter unit having a first opening and a second opening, the first opening being disposed closer to the first substrate mounting member than the second opening, the second opening being disposed closer to the second substrate mounting member than the first opening.

2. The deposition apparatus of claim 1, further comprising:
a chamber containing the sputter unit; and
a driving unit configured to move at least one of the first substrate mounting member and the second substrate mounting member with respect to at least one of the chamber and the sputter unit.

3. The deposition apparatus of claim 1,
wherein the first substrate mounting member has an opening located between two portions of the first substrate mounting member, and
wherein a width of the opening is equal to or greater than a length of the sputter unit in a direction parallel to a direction of the width of the opening.

4. The deposition apparatus of claim 3, wherein the two portions of the first substrate mounting member do not overlap the sputter unit in a direction perpendicular to the direction of the width of the opening.

5. The deposition apparatus of claim 1, wherein the first substrate mounting member and the second substrate mounting member are configured to simultaneously move in a same direction with respect to the sputter unit.

6. The deposition apparatus of claim 1,
wherein the first opening is located at a first side of the sputter unit,
wherein the second opening is located at a second side of the sputter unit that is parallel to the first side of the sputter unit, and
wherein the first opening overlaps the second opening in a direction perpendicular to the first side of the sputter unit.

7. The deposition apparatus of claim 6, further comprising: a first target support member and second target support member that are disposed between the first side of the sputter unit and the second side of the sputter unit, wherein the first target support member overlaps the second target support member in a direction parallel to the first side of the sputter unit.

8. The deposition apparatus of claim 1, further comprising: a control unit configured to control a height of the sputter unit in a direction parallel to the first substrate mounting member.

9. The deposition apparatus of claim 1, further comprising:
a first press plate configured to secure a first substrate on the first substrate mounting member; and
a second press plate disposed parallel to the first press plate and configured to secure a second substrate on the second substrate mounting member.

10. The deposition apparatus of claim 9, further comprising: a target support member disposed inside the sputter unit and having a support surface configured to contact a target that includes deposition material, wherein the first press plate has a contact surface disposed perpendicular to the support surface and configured to contact the first substrate.

11. The deposition apparatus of claim 9, further comprising: a target support member disposed inside the sputter unit and having a support surface configured to contact a target that includes deposition material, wherein the first press plate includes a flow passage disposed perpendicular to the support surface and configured to transmit a refrigerant for cooling the first substrate.

12. The deposition apparatus of claim 9, further comprising a pipe connected to a flow passage of the first press plate and connected to a connection unit of the first substrate mounting member, the flow passage of the first press plate being configured to receive a refrigerant provided through the connection unit of the first substrate mounting member and being configured to transmit the refrigerant for cooling the first substrate.

13. The deposition apparatus of claim 12, further comprising a tube connected to the connection unit of the first substrate mounting member, configured to transmit the refrigerant to the connection unit of the first substrate mounting member, and configured to deform when the first substrate mounting member moves with respect to the sputter unit.

14. A method for manufacturing a display apparatus, the method comprising:
disposing a sputter unit between a first display unit and a second display unit, the sputter unit having a first opening and a second opening, the first display unit being disposed on a first substrate, the second display unit being disposed on a second substrate; and
simultaneously providing a first set of material through the first opening onto the first display unit and providing a second set of material through the second opening onto the second display unit.

15. The method of claim 14, wherein at least one of the first set of material and the second set of material includes a low temperature viscosity transition (LVT) inorganic material.

16. The method of claim 14, further comprising: simultaneously moving the first display unit and the second display unit in a same direction with respect to the sputter unit.

17. The method of claim 14, further comprising: mounting the first substrate on a first substrate mounting member,
wherein the first substrate mounting member has an opening located between two portions of the first substrate mounting member, and
wherein a width of the opening parallel to a first coordinate axis is equal to or greater than a length of the sputter unit parallel to the first coordinate axis.

18. The method of claim 17, wherein the two portions of the first substrate mounting member do not overlap the sputter unit in a direction perpendicular to the first coordinate axis.

19. The method of claim 14, further comprising:
mounting the first substrate on a first substrate mounting member;
using a press plate to secure the first substrate on the first substrate mounting member; and
providing a refrigerant through a flow passage of the press plate to cool the first substrate.

20. The method of claim 14, further comprising:
supporting the sputter unit on a ground surface; and
disposing each of the first substrate and the second substrate perpendicular to the ground surface.
